(19) United States
(12) Patent Application Publication
(10) Pub. No.: US 2017/0263770 A1
(43) Pub. Date: Sep. 14, 2017

(54) SEMICONDUCTOR DEVICE AND MANUFACTURING METHOD OF THE SAME

(71) Applicant: KABUSHIKI KAISHA TOSHIBA, Tokyo (JP)

(72) Inventor: Masakazu GOTO, Yokohama Kanagawa (JP)

(21) Appl. No.: 15/253,992

(22) Filed: Sep. 1, 2016

(30) Foreign Application Priority Data
Mar. 8, 2016 (JP) 2016-044677

(51) Int. Cl. H01L 29/78; H01L 29/06; H01L 29/66; H01L 29/08; H01L 29/45

(52) U.S. Cl. CPC H01L 29/7835; H01L 29/0847; H01L 29/456; H01L 29/66659; H01L 29/665; H01L 29/0649

(57) ABSTRACT

A semiconductor device includes a first source region, a second source region, and a drain region. The first source region includes a first conductivity type that is formed in a semiconductor layer. The second source region includes a second conductivity type that is adjacent to a gate region and formed in the first source region, the second source region being electrically connected to the first source region, and configured such that one end of a first face of the second source region abuts a gate insulating film formed in the gate region and at least a portion of a second face opposite to the first face abuts the first source region. The drain region includes the first conductivity type that is formed adjacent to the gate region in the semiconductor layer with the gate region interposed with the second source region and the drain region.

### CROSS-REFERENCE TO RELATED APPLICATION

This application is based upon and claims the benefit of priority from Japanese Patent Application No. 2016-044677, filed Mar. 8, 2016, the entire contents of which are incorporated herein by reference.

### FIELD

Embodiments described herein relate generally to a semiconductor device and a manufacturing method of the same.

### BACKGROUND

In recent years, a TFET (Tunnel Field-Effect Transistor, or simply, tunnel transistor) has been actively studied in response to a need for a higher performing and a lower power usage transistor relative to a MOSFET (Metal-Oxide-Semiconductor Field-Effect Transistor). The TFET can provide a drain current, with respect to a gate voltage, in a subthreshold region, and flows in a steep subthreshold slope exceeding a theoretical value of the subthreshold slope of the MOSFET. That is, in a case where the same voltage is applied to the gate of the TFET and the gate of the MOSFET, the TFET can provide a larger drain current when compared to the MOSFET, and a lower power consumption is expected.

However, the TFET reversely connects the source and the drain (PN junction). Therefore, the PN junction is biased in a forward direction depending on a potential between the source and the drain. As a result, a large current may flow between the source and the drain even in an OFF state. Since this current cannot be controlled by the gate, the current becomes a leakage current of the transistor in the OFF state.

### DESCRIPTION OF THE DRAWINGS

FIG. 1 is a diagram schematically illustrating a semiconductor device according to an embodiment.

FIGS. 2A to 2C are diagrams schematically illustrating a process of forming the semiconductor device according to the embodiment.

FIGS. 3A to 3C are diagrams schematically illustrating a process of forming a gate electrode of the semiconductor device according to the embodiment.

FIGS. 4A to 4C are diagrams schematically illustrating a process of forming a second source region of the semiconductor device according to the embodiment.

FIGS. 5A and 5B are diagrams schematically illustrating a process after forming the second source region of the semiconductor device according to the embodiment.

FIG. 6 is a diagram illustrating a simulation result of the semiconductor device according to the embodiment.

FIGS. 7A and 7B are diagrams illustrating a simulation result on a current of the semiconductor device according to the embodiment.

### DETAILED DESCRIPTION

According to an embodiment, there is provided a TFET which can suppress a leakage current.

In general, according to an embodiment, a semiconductor device includes a first source region, a second source region, and a drain region. The first source region is a region of a first conductivity type that is formed in a semiconductor layer. The second source region is a region of a second conductivity type that is adjacent to a gate region and formed in the first source region, the second source region being electrically connected to the first source region, and configured such that one end of a first face of the second source region abuts on a gate insulating film formed in the gate region and at least a portion of a second face opposite to the first face abuts on the first source region. The drain region is a region of the first conductivity type that is formed adjacent to the gate region in the semiconductor layer with the gate region interposed with respect to the second source region.

Hereinafter, one embodiment of the disclosure will be described with reference to the drawings. This embodiment does not limit the disclosure.

The semiconductor device according to the embodiment is a tunnel transistor which includes a drain region of a first conductivity type and a second source region of a second conductivity type which is covered with a first source region of the first conductivity type configured as a barrier layer. The semiconductor device is used to generate a drain current between the second source region and the drain region, and on the other hand, to suppress a leakage current when a gate voltage is not applied (an OFF state). A more detailed description will be made below.

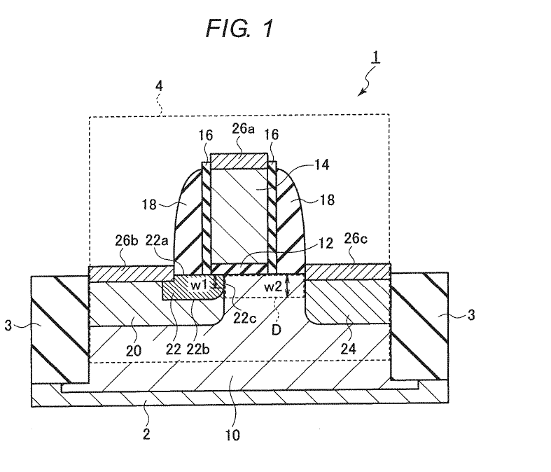

FIG. 1 is a cross-sectional view illustrating a semiconductor device 1 according to this embodiment. As illustrated in FIG. 1, the semiconductor device 1 includes a semiconductor substrate 2, an element isolation area 3, and a tunnel transistor 4.

The semiconductor substrate 2 is a so-called wafer, and is a substrate where the tunnel transistor 4 is formed. The semiconductor substrate 2 contains silicon for example. The element isolation area 3 is formed in the semiconductor substrate 2 to electrically isolate the tunnel transistor 4 from the other areas. The element isolation area 3 is a silicon oxide film (SiO₂) for example, and corresponds to an STI (Shallow Trench Isolation) film in this embodiment.

The tunnel transistor 4 is formed on the semiconductor substrate 2. The tunnel transistor 4 is, for example, an N-type tunnel transistor which is provided with an N-type (the first conductivity type) drain region and a P-type (the second conductivity type) source region. In the tunnel transistor 4, the drain current flows between source and drain based on a voltage difference between gate and source and/or a difference in electrical potential between drain and source. As illustrated in FIG. 1, the tunnel transistor 4 includes a well region 10, a gate insulating film 12, a gate electrode 14, a first side wall 16, a second side wall 18, a first source region 20, a second source region 22, a drain region 24, and silicide layers 26a, 26b, and 26c.

In this embodiment, a gate region provided with the gate insulating film 12, the gate electrode 14, the first side wall 16, and the second side wall 18 is formed on the well region 10 (a semiconductor layer). The first source region 20 is an N-type source region which is formed in the well region 10, and is configured as a barrier layer of the second source region 22. The second source region 22 is adjacent to the gate region, and is formed in the first source region 20. The second source region 22 is electrically connected to the first source region 20, in which one end of a first face 22a abuts on the gate insulating film 12 formed in the gate region, and a second face 22b positioned on the opposite side of the second source region 22 from the first face 22a is covered by the first source region 20. The drain region 24 is formed in the well region 10 to interpose the gate region with respect to the first source region 20 and the second source region 22, and is arranged adjacent to the gate region. A configuration of the tunnel transistor 4 will be described in detail with reference to FIG. 1.

The well region 10 is a layer which is formed in the semiconductor substrate 2 to electrically isolate transistors from each other. The well region 10 may be a P-type (P-) region having a low dopant concentration, a semiconductor layer having an impurity concentration equal to or less than 10¹⁶/cm³ (a so-called intrinsic semiconductor layer), or an N-type (N-) region having a low dopant concentration. Further, a channel region (not illustrated) may be formed as a semiconductor layer having different dopant concentration and polarity from those of the well region 10 in order to adjust a threshold voltage of the tunnel transistor. The polarity of the channel region may also be same as the well region 10. The tunnel transistor 4 may be configured in the channel region.

The gate insulating film 12 is an insulating film which is arranged between the gate electrode 14 and the well region 10. For example, the gate insulating film 12 may be a silicon oxide film (SiO₂), a silicon oxynitride film (SiON), or a high-permittivity insulating film such as a nitrogen-added hafnium silicate film (HfSiON).

The gate electrode 14 applies a voltage for the generation of a tunnel current in an upper portion of the well region 10. The gate electrode 14 contains silicon or metal for example, and is formed on the semiconductor substrate 2 through the gate insulating film 12.

The first side wall 16 is a so-called offset spacer, and is formed to abut a side surface of the gate electrode 14 in order to control a position of the first source region 20. The first side wall 16 is formed by a silicon nitride film (SiN) for example. The second side wall 18 is an insulating film which is formed on both sides of the gate electrode 14 through the first side wall 16. The second side wall 18 is formed by the silicon oxide film (SiO₂), for example.

The first source region 20 is formed to abut the second source region 22 in the semiconductor substrate 2, and to cover the lower portion of the second source region 22 (i.e. the second face 22b). The first source region 20 is an N-type (N+) region having a high dopant concentration of about 10¹⁹ to 10²⁰/cm³, for example.

The second source region 22 is a so-called source extension region. The second source region 22 is adjacent to the first source region 20, and has the first face 22a of which the one end abuts on the gate insulating film 12 such that the first face 22a is selectively exposed from the semiconductor substrate 2. Furthermore, the second face 22b on the opposite side of the second source region 22 from the first face 22a is formed in the well region 10 abutting the first source region 20 at least in a portion thereof. A third face 22c, which is a face between the first face 22a and the second face 22b immediately below the gate insulating film 12, is formed to abut the well region 10 at least in a portion. The drain current flows between the second source region 22 and the drain region 24 by a voltage applied to the second source region 22, the gate electrode 14, and the drain region 24. The second source region 22 is, for example, a P-type (P+) region having a high dopant concentration of about 10¹⁹ to 10²⁰/cm³.

The second source region 22 is preferably formed such that an area of the second face 22b abutting on the well region 10 is small in order to increase a depression effect of the leakage current. More preferably, the second source region 22 is formed to be covered with the first source region 20 as illustrated in FIG. 1. In addition, the third face 22c abuts on the well region 10 at least in a portion. In a case where a voltage equal to or less than a threshold voltage is applied to the gate electrode 14 (the OFF state of the transistor), it is preferable that an area where no depletion layer D exists in the well region 10 be small. More preferably, a width w1 of the region where the third face 22c abuts on the well region 10 is smaller than a width w2 of the depletion layer D (for example, a width equal to or less than 20 nm).

The drain region 24 is formed in the semiconductor substrate 2 to abut the gate region on the side of the gate region opposite from the first source region 20 and the second source region 22 with the gate electrode 14 interposed therebetween. In other words, the drain region 24 is formed in the well region 10 facing the third face 22c of the second source region 22 through the well region 10. The drain region 24 is, for example, an N-type (N+) region having a high dopant concentration of about 10¹⁹ to 10²⁰/cm³.

The silicide layers 26a, 26b, and 26c are respectively formed on the gate electrode 14, the first source region 20, the second source region 22, and the drain region 24. In particular, the silicide layer 26b formed on the first source region 20 and the second source region 22 is formed as a source electrode which electrically connects the first source region 20 and the second source region 22. In other words, the first source region 20 and the second source region 22 are kept at the same potential through the silicide layer 26b arranged thereon. The gate voltage is applied to the gate electrode 14 through the silicide layer 26a. A source voltage is applied to the first source region 20 and the second source region 22 through the silicide layer 26b. Then, a drain voltage is applied to the drain region 24 through the silicide layer 26c.

Further, although the tunnel transistor 4 has been described above as an N-type transistor, the tunnel transistor 4 may be a P-type transistor. In such embodiments, the first source region 20 and the drain region 24 are formed as P-type regions (i.e. the first conductivity type is P-type) and the second source region 22 is formed as an N-type region (the second conductivity type is N-type). The semiconductor device 1 to be described below is formed in the same process. In other words, this embodiment will be described using a process related to the N-type tunnel transistor, but may be implemented by a process of the P-type tunnel transistor by appropriately replacing or changing a type of dopant accordingly.

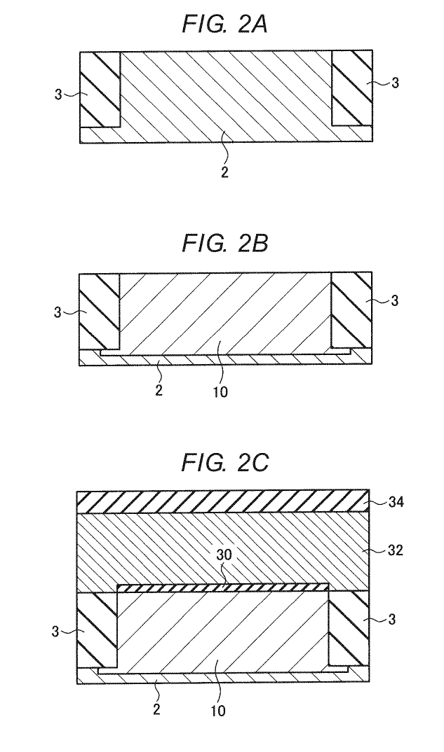

Next, the description will be made about a method of manufacturing the semiconductor device which is provided with the tunnel transistor 4 according to this embodiment. FIGS. 2A to 5B are drawings illustrating a procedure of the method of manufacturing the semiconductor device according to this embodiment.

First, as illustrated in FIG. 2A, the element isolation area 3 is formed in the semiconductor substrate 2 to prevent electrical connections to other transistors through the substrate 2. For example, the element isolation area 3 is formed as an insulator by performing the STI process on the semiconductor substrate 2. With this procedure, an area is formed to be electrically isolated from the other portions of the semiconductor substrate 2.

Next, as illustrated in FIG. 2B, P-type dopants are introduced by lithography and ion implantation to the region electrically isolated by the element isolation area 3 to form the semiconductor layer serving as the well region 10. As a type of the ion to be implanted, B (boron) ions are used, or in a case where an N-type well region is formed, P (phosphorus) ions are used, for example.

Next, as illustrated in FIG. 2C, the gate region is formed on the semiconductor substrate 2 between the element isolation areas 3. First, a gate insulating film material 30 serving as the gate insulating film 12 is formed on the semiconductor layer serving as the well region 10 by a thermal oxidation method. The gate insulating film material 30 is formed using the silicon oxide film for example. Subsequently, a gate electrode material 32 serving as the gate electrode 14 is formed on the semiconductor substrate 2 according to a CVD (Chemical Vapor Deposition) method. The gate electrode material 32 is formed by stacking polysilicon for example. After forming the polysilicon, N-type dopants are introduced to the gate electrode material by ion implanting. As a type of dopant to be implanted, P ions are used, for example. Subsequently, a gate hard mask material 34 is stacked on the entire surface of the gate electrode material 32 by the CVD method again. The gate hard mask material 34 is formed using SiN, for example.

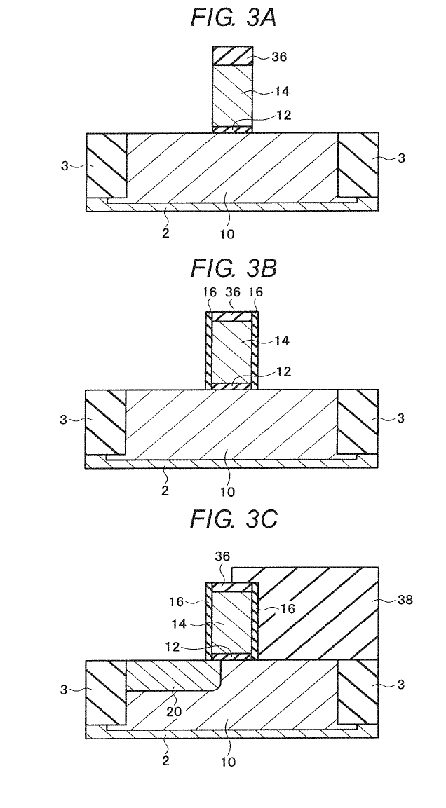

Next, as illustrated in FIG. 3A, the hard mask material 34 and the gate electrode material 32 are patterned according to lithography and RIE (Reactive Ion Etching) method. Furthermore, the gate insulating film material 30 is processed according to a wet etch process such as DHF (diluted hydrofluoric acid) for example. With this procedure, the gate electrode 14 is formed over the gate insulating film 12, and the upper surface of the gate electrode 14 comes to be masked by a gate hard mask 36.

Next, as illustrated in FIG. 3B, the first side wall 16 is formed on the side surface of the gate electrode 14. The first side wall 16 is an insulating film. For example, the first side wall 16 is formed such that an insulating film material for the first side wall 16 is formed on the entire surface on the semiconductor substrate 2 according to the CVD method, and the insulating film material is anisotropically etched according to the RIE. The first side wall 16 has a thickness of several nm, for example.

Next, as illustrated in FIG. 3C, a region to be formed as the drain region 24 in a subsequent procedure is covered with a resist film 38. Then, ions are implanted to form a semiconductor layer serving as the first source region 20 using the resist film 38 as a mask. As a type of dopant used in implantation, an As (arsenic) ion or a P ion is used, for example.

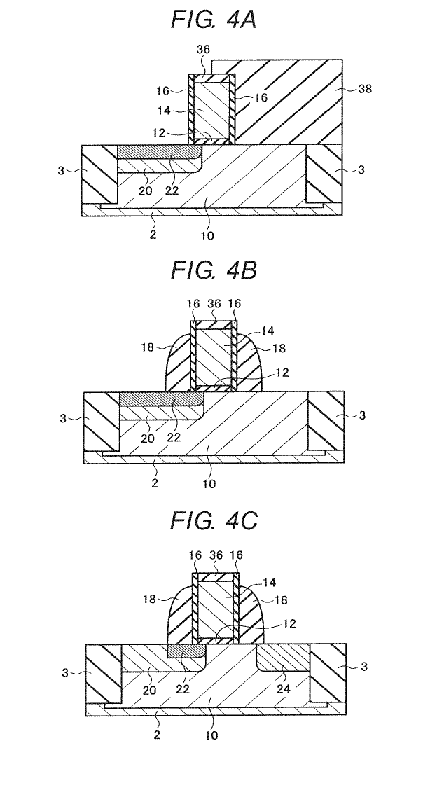

Next, as illustrated in FIG. 4A, ions are implanted to form the source extension region (that is, a semiconductor layer serving as the second source region 22) using the resist film 38 as a mask. As a type of dopant used in implantation, a B ion is used, for example. In addition, dosage is adjusted such that the impurity, or dopant, concentration becomes higher than that of the formed semiconductor layer serving as the first source region 20. Further, the source extension region is formed at a shallow depth, compared to the semiconductor layer serving as the first source region 20 formed in the previous procedure, by adjusting an acceleration voltage of the ion implantation. As a type of dopant used in implantation, the B ion is used, for example.

Next, as illustrated in FIG. 4B, after removing the resist film 38, the second side wall 18 is formed as an insulator on the side surface of the gate electrode 14 (covered by the first side wall 16). For example, the second side wall 18 is formed such that an insulating film material for the second side wall 18 is formed on the entire surface of the semiconductor substrate 2 according to the CVD method and the insulating film material is anisotropically etched according to the RIE. The film thickness of the second side wall 18 is several tens nm for example.

Next, as illustrated in FIG. 4C, ions are implanted to form the semiconductor layer serving as the first source region 20 and the semiconductor layer serving as the drain region 24 using the second side wall 18 as a spacer. As a type of dopant used in implantation, the As ion or the P ion is used, for example. At this time, the impurity concentration is set to be sufficiently higher than that of the second source region 22 by adjusting the dosage. The ions are implanted in an outside region of the gate electrode 14 through the second side wall 18. The semiconductor layer that forms the second source region 22 is compensated by increasing the impurity concentration as described above. The procedure of forming the two semiconductor layers may be separately performed by masking the regions using the respective resist films formed thereon, or the procedure of the semiconductor manufacturing process may be performed in less time by forming the two layers at the same time.

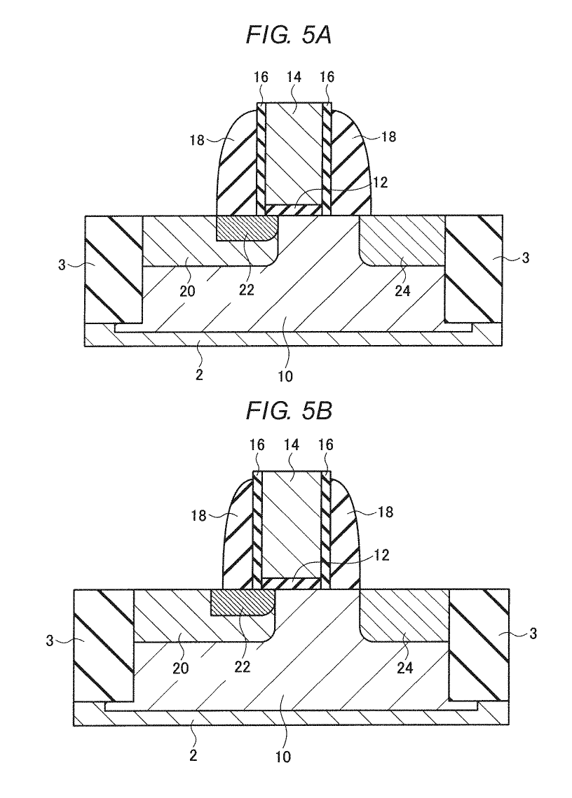

Next, as illustrated in FIG. 5A, the dopants introduced by the ion implantation are activated by an annealing procedure after the gate hard mask 36 is removed. For example, the gate hard mask 36 is removed using hot phosphoric acid, and then spike annealing is performed at 1,000° C.

Next, as illustrated in FIG. 5B, the thickness of the second side wall 18 is adjusted such that the second source region 22 is exposed outside of the second side wall 18. For example, the second side wall 18 is made thinner through a wet etching such as DHF, so that the thickness is adjusted.

Then, finally, a metal such as Ni (nickel) is formed on the entire surface of the wafer and annealed to cause a silicide reaction with respect to the Si substrate and the polysilicon gate electrode, so that the silicide layers 26a, 26b, and 26c are formed in a self-aligned manner. With this procedure, as illustrated in FIG. 1, the silicide layer 26a is formed on the gate electrode 14, the silicon layer 26b is formed on the first source region 20 and the second source region 22, and the silicide layer 26c is formed on the drain region 24.

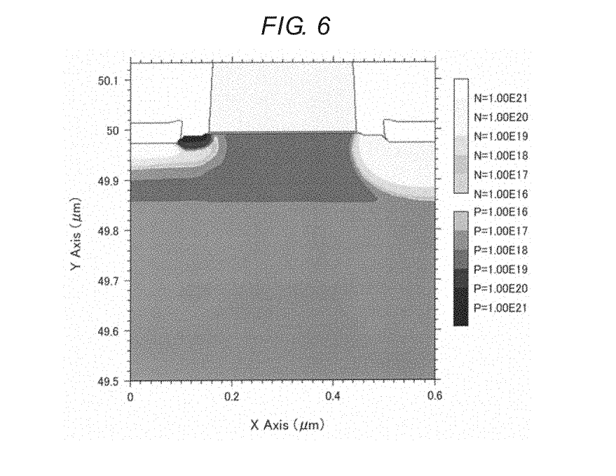

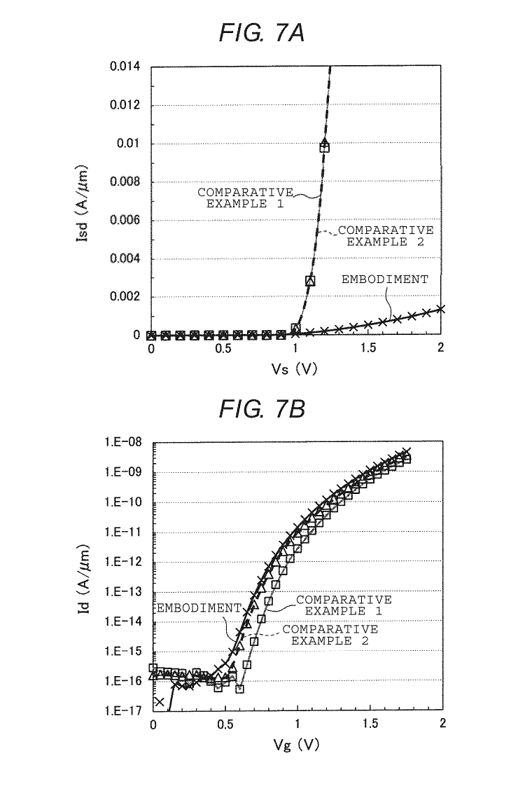

FIGS. 6, 7A, and 7B illustrate simulation results of the semiconductor device 1 according to this embodiment using TCAD (Technology Computer Aided Design). FIG. 6 illustrates the impurity concentration of the semiconductor layer of the semiconductor device 1 according to this embodiment on a gray scale. As illustrated by the gray scale on the right side of FIG. 6, a lighter shading indicates the N-type impurity concentration is high and a darker shading indicates the P-type impurity concentration is high. The vertical axis and the horizontal axis indicate the Y axis and the X axis respectively when the semiconductor device is viewed in cross section. The unit of the axis is “μm”. As illustrated in FIG. 6, the first source region 20 and the drain region 24 are semiconductor layers having a high dopant concentration of the N type (the first conductivity type). The second source region 22 is the semiconductor layer having a high dopant concentration of the P type (the second conductivity type).

FIG. 7A is a graph illustrating the leakage current when the semiconductor device 1 illustrated in FIG. 6 is turned off. For example, the graph shows the leakage current flowing in a case where the gate voltage and the drain voltage are set as 0 V, and a predetermined positive voltage is applied as the source voltage. As a comparative example, a case where there is no first source region 20 (Comparative Example 1: a solid line), and a case where there is no first source region 20 and an N-type Halo is introduced below the second source region 22 (Comparative Example 2: a broken line) are plotted. The leakage current of the semiconductor device 1 according to this embodiment is about 1/100 of the leakage current of the Comparative Examples 1 and 2.

Similarly, FIG. 7B is a graph illustrating an ON-state current of the semiconductor device 1 illustrated in FIG. 6. Similarly to FIG. 7A, the result of the semiconductor device 1 according to this embodiment is depicted together with Comparative Examples 1 and 2. As illustrated in FIG. 7B, the semiconductor device 1 according to this embodiment provides a drain current in the ON state substantially the same as that in Comparative Examples 1 and 2.

As described above, in the drain region of the first conductivity type and the source region of the second conductivity type forming the tunnel transistor according to this embodiment, the source region of the first conductivity type is formed to cover the source region of the second conductivity type such that at least a portion of the source region of the second conductivity type abuts on the well region. Therefore, a desirable ON-state current is obtained as illustrated in FIG. 7B, and the leakage current of the transistor in the OFF state can be suppressed as illustrated in FIG. 7A.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first source region of a first conductivity type that is formed in a semiconductor layer;
a second source region of a second conductivity type that is adjacent to a gate region and formed in the first source region, the second source region being electrically connected to the first source region, and configured such that one end of a first face of the second source region abuts a gate insulating film formed in the gate region and at least a portion of a second face opposite to the first face abuts the first source region; and
a drain region of the first conductivity type that is formed adjacent to the gate region in the semiconductor layer with the gate region interposed with respect to the second source region and the drain region.

2. The semiconductor device according to claim 1,
wherein at least a portion of a third face of the second source region facing the drain region abuts the semiconductor layer outside of the first source region.

3. The semiconductor device according to claim 2,
wherein a width of the third face abutting the semiconductor layer is smaller than that of a depletion layer generated in the semiconductor layer in a case where a voltage equal to or less than a predetermined value is applied to the gate region.

4. The semiconductor device according to claim 2,
wherein the second source region is arranged such that the second face is covered by the first source region.

5. The semiconductor device according to claim 2, further comprising:
a silicide layer that electrically connects the first source region and the second source region.

6. The semiconductor device according to claim 1,
wherein a width of the third face abutting the semiconductor layer is smaller than that of a depletion layer generated in the semiconductor layer in a case where a voltage equal to or less than a predetermined value is applied to the gate region.

7. The semiconductor device according to claim 6,
wherein the second source region is arranged such that the second face is covered by the first source region.

8. The semiconductor device according to claim 6, further comprising:
a silicide layer that electrically connects the first source region and the second source region.

9. The semiconductor device according to claim 1,
wherein the second source region is arranged such that the second face is covered by the first source region.

10. The semiconductor device according to claim 9, further comprising:
a silicide layer that electrically connects the first source region and the second source region.

11. The semiconductor device according to claim 1, further comprising:
a silicide layer that electrically connects the first source region and the second source region.

12. A semiconductor device, comprising:
a first source region of a first conductivity type that is formed in a semiconductor layer on a substrate;
a second source region of a second conductivity type formed in a portion of the first source region that is adjacent to a gate region, the second source region being electrically connected to the first source region, and configured such that one end of a first face of the second source region abuts a gate insulating film formed in the gate region and at least a portion of a second face opposite to the first face abuts the first source region; and
a drain region of the first conductivity type that is formed adjacent to the gate region in the semiconductor layer, with the gate region interposed with respect to the second source region and the drain region, wherein at least a portion of a third face of the second source region facing the drain region abuts the semiconductor layer outside of the first source region.

13. The semiconductor device according to claim 12,
wherein a width of the third face abutting the semiconductor layer is smaller than that of a depletion layer generated in the semiconductor layer in a case where a voltage equal to or less than a predetermined value is applied to the gate region.

14. The semiconductor device according to claim 12,
wherein the second source region is arranged such that the second face is covered by the first source region.

15. The semiconductor device according to claim 12, further comprising:
a silicide layer that electrically connects the first source region and the second source region.

16. The semiconductor device according to claim 12,
wherein a width of the third face abutting the semiconductor layer is smaller than that of a depletion layer generated in the semiconductor layer in a case where a voltage equal to or less than a predetermined value is applied to the gate region.

17. The semiconductor device according to claim 16,
wherein the second source region is arranged such that the second face is covered by the first source region.

18. The semiconductor device according to claim 16, further comprising:
a silicide layer that electrically connects the first source region and the second source region.

19. The semiconductor device according to claim 12,
wherein the second source region is arranged such that the second face is covered by the first source region.

20. A method of manufacturing a semiconductor device, comprising:
forming a first semiconductor layer on a substrate;
forming a first electrode on the first semiconductor layer, the first electrode being separated from the first semiconductor layer by an insulating film, wherein the first semiconductor layer is divided into two regions by the first electrode;
forming a first side wall insulator on a side surface of the first electrode;
forming a second semiconductor layer of a first conductivity type on a surface of a first region of the first semiconductor layer;
forming a third semiconductor layer of a second conductivity type on the first semiconductor layer to partially cover the second semiconductor layer;
forming a second side wall insulator on a side surface of the first side wall;
forming a fourth semiconductor layer of the first conductivity type on a surface side of a second region of the first semiconductor layer;
forming a fifth semiconductor layer of the first conductivity type on the third semiconductor layer;
thinning the second side wall to expose a portion of the third semiconductor layer; and
forming a second electrode on the fourth semiconductor layer, and forming a third electrode in the exposed portion of the third semiconductor layer and on the fifth semiconductor layer such that the third semiconductor layer and the fifth semiconductor layer are electrically connected to each other.
